(19) United States
(12) Patent Application Publication
(10) Pub. No.: US 2025/0261302 A1
(43) Pub. Date: Aug. 14, 2025

(54) WIRING SUBSTRATE AND MANUFACTURING METHOD OF WIRING SUBSTRATE

(71) Applicant: TOPPAN Holdings Inc., Tokyo (JP)

(72) Inventor: Yuki UMEMURA, Tokyo (JP)

(73) Assignee: TOPPAN Holdings Inc., Tokyo (JP)

(21) Appl. No.: 19/196,863

(22) Filed: May 2, 2025

Related U.S. Application Data
(63) Continuation of application No. PCT/JP2023/036775, filed on Oct. 10, 2023.

(30) Foreign Application Priority Data
Nov. 14, 2022 (JP) 2022-181881

(51) Int. Cl. H05K 1/02; H05K 1/03; H05K 1/11; H05K 3/00; H05K 3/07; H05K 3/28

(52) U.S. Cl. CPC H05K 1/0242; H05K 1/0306; H05K 1/115; H05K 3/0029; H05K 3/07; H05K 3/282; H05K 2201/09454; H05K 2201/09481; H05K 2201/09527; H05K 2201/09618

(57) ABSTRACT

A wiring substrate includes: a glass substrate, a conductor layer and an insulator. The glass substrate has a first surface and a second surface serving as a back surface of the first surface and is provided with one or more through holes each extending from the first surface to the second surface. The conductor layer is provided on a side wall of each of the one or more through holes and the second surface. The insulator is provided on an inside of each of the one or more through holes. A surface roughness of the conductor layer provided on the side wall of each of the one or more through holes is larger than a surface roughness of the conductor layer provided on the second surface.

### CROSS-REFERENCE TO RELATED APPLICATIONS

This application is a Continuation Application of PCT Application No. PCT/JP2023/036775, filed Oct. 10, 2023 and based upon and claiming the benefit of priority from Japanese Patent Application No. 2022-181881, filed Nov. 14, 2022, the entire contents of all of which are incorporated herein by reference.

### FIELD

Embodiments of the present invention relate to a wiring substrate and a manufacturing method of the wiring substrate.

### BACKGROUND

In recent years, electronic devices have been using signals with higher frequencies in accordance with an increase in function and decrease in size, so that multilayer wiring substrates represented by an interposer mounted on an electronic device are also required to be adapted to high frequencies.

Especially in recent multilayer wiring substrates, a glass substrate is used, and a through electrode is provided by forming a through hole in the glass substrate. A multilayer wiring substrate in which a conductor layer, an insulating resin layer, and another conductor layer are sequentially laminated on both surfaces of a glass substrate is used.

Through electrodes used in multilayer wiring substrates include a conformal-type electrode (conformal via) formed of a conductor not embedded in a through hole, and a filling-type electrode (filled via) embedded in the through hole. In a case of the conformal type, no electrode is embedded in the through electrode, thereby enabling a reduction in a manufacturing cost and a stress caused by the through electrode. On the other hand, since the wiring portion cannot be arranged to overlap a part provided with the through hole, it is difficult to design a higher-scale integration.

International Publication No. 2017/209296 discloses a technique of arranging a conductor so as to close a substrate surface side of a through hole even in a conformal-type through electrode. Such a technique is disclosed that facilitates a higher-scale integration by efficiently arranging, in the above manner, a wiring portion on at least one surface side of a substrate.

Furthermore, a multilayer wiring substrate is required to be more compact, more functional, and lower in height depending on the application; however, a problem such as a crack in a glass core substrate is likely to occur in manufacturing steps of the multilayer wiring substrate in a case where the thickness of the glass substrate reaches about 100 μm.

Thus, in order to prevent such a crack, International Publication No. 2019/235617 proposes steps in which a support body is bonded to a glass substrate via a release layer and is peeled off after wiring is formed.

Specifically, International Publication No. 2019/235617 proposes a manufacturing method of a wiring substrate which has a step of forming a first wiring on a first surface of a glass substrate, a step of supporting, with a support body, a first wiring side of the glass substrate on which the first wiring is formed, a step of forming a laser modified portion, which serves as a starting point for the formation of a through hole, on the glass substrate using a laser irradiated from the surface opposite to the first surface, a step of forming a through hole while thinning the glass substrate by performing etching from the surface opposite to the first surface of the glass substrate toward the first surface using a hydrogen fluoride etching solution, a step of forming, after the step of forming the through hole, a through electrode inside the through hole while forming a second wiring on the surface opposite to the first surface of the glass substrate, thereby connecting the first wiring and the second wiring via the through electrode, and a step of removing the support body from the glass substrate after the formation of the second wiring.

### SUMMARY

However, with structures and manufacturing methods described in International Publication No. 2017/209296 and International Publication No. 2019/235617, in which a through electrode is formed in a closed through hole and second wiring is formed on the surface opposite to the first surface of the glass substrate, and an insulating resin layer is then formed, it is difficult to ensure adhesion between the surface of the electrode inside the through hole and the insulating resin, and reliability may be impaired.

The present invention has been made in view of the above problem, and an object of the present invention is to provide a highly reliable wiring substrate and a manufacturing method of the wiring substrate.

According to one aspect of the present invention, there is provided a wiring substrate comprising: a glass substrate which has a first surface and a second surface serving as a back surface of the first surface and is provided with one or more through holes each extending from the first surface to the second surface; a conductor layer provided on a side wall of each of the one or more through holes and the second surface; and an insulator provided on an inside of each of the one or more through holes, wherein a surface roughness of the conductor layer provided on the side wall of each of the one or more through holes is larger than a surface roughness of the conductor layer provided on the second surface.

According to another aspect of the present invention, there is provided the wiring substrate in the above aspect, wherein an arithmetic surface roughness Ra of the conductor layer provided on the side wall of each of the one or more through holes is 150 nm or greater and 1000 nm or smaller.

According to still another aspect of the present invention, there is provided the wiring substrate in the above aspect, wherein the arithmetic surface roughness Ra of the conductor layer provided on the second surface is 100 nm or smaller.

According to still another aspect of the present invention, there is provided the wiring substrate in any one of the above aspects, further comprising a corrosion prevention film having a discontinuous portion and provided between the conductor layer and the insulator, the conductor layer being provided on the side wall of each of the one or more through holes.

According to still another aspect of the present invention, there is provided the wiring substrate in any one of the above aspects, wherein the surface roughness of the conductor layer provided on the side wall of each of the one or more through holes increases in a direction from a side close to the second surface to a side close to the first surface. According to still another aspect of the present invention, there is provided the wiring substrate in any one of the above aspects, wherein the surface roughness of the conductor layer provided on the side wall of each of the one or more through holes increases in a direction from a side close to the first surface to a side close to the second surface.

According to still another aspect of the present invention, there is provided a manufacturing method of a wiring substrate, comprising: forming a first conductor layer on a first surface of a glass substrate having the first surface and a second surface serving as a back surface of the first surface; forming one or more modified portions on the glass substrate by irradiating the glass substrate with a laser light; forming one or more through holes at positions of the one or more modified portions, respectively, by etching the second surface of the glass substrate on which the first conductor layer is formed; and forming a second conductor layer on the second surface of the glass substrate and the inner wall of each of the one or more through holes, wherein a surface roughness of the second conductor layer provided on the inner wall of each of the one or more through holes is larger than a surface roughness of the second conductor layer provided on the second surface.

According to still another aspect of the present invention, there is provided the manufacturing method of the wiring substrate in the above aspect, wherein forming the second conductor layer includes: providing a seed layer on the second surface of the glass substrate and the inner wall of each of the one or more through holes; forming the second conductor layer on the seed layer by electrolytic copper plating; and removing an unnecessary portion from the seed layer by etching, wherein the one or more through holes is smaller in liquid flow amount in the electrolytic copper plating than the second surface.

According to still another aspect of the present invention, there is provided the manufacturing method of the wiring substrate in any one of the above aspects, wherein forming the second conductor layer includes: providing a seed layer on the second surface of the glass substrate and the inner wall of each of the one or more through holes; forming the second conductor layer on the seed layer by electrolytic copper plating; forming a corrosion prevention film having a discontinuous portion on a part of the second conductor layer, the part being provided on the inner wall of each of the one or more through holes; and etching the second conductor layer such that a part on which the corrosion prevention film is not formed is smaller in film thickness than the part on which the corrosion prevention film is formed.

According to still another aspect of the present invention, there is provided the manufacturing method of the wiring substrate in the above aspect, wherein forming the corrosion prevention film having the discontinuous portion includes: providing, on the second surface of the glass substrate, a mask having an opening at each of positions of the one or more through holes; providing, on the inner wall of each of the one or more through holes, the corrosion prevention film having the discontinuous portion; and removing the mask.

According to still another aspect of the present invention, there is provided the manufacturing method of the wiring substrate in any one of the above aspects, wherein forming the corrosion prevention film having the discontinuous portion includes: providing, on the second surface of the glass substrate and the inner wall of each of the one or more through holes, a corrosion prevention film which is a continuous film; and removing the corrosion prevention film from the second surface of the glass substrate by dry etching and also forming the corrosion prevention film having the discontinuous portion on the inner wall of each of the one or more through holes.

According to the present invention, it is possible to provide a highly reliable wiring substrate and a manufacturing method of the wiring substrate.

### BRIEF DESCRIPTION OF THE DRAWINGS

FIG. 1 is a cross-sectional view of a wiring substrate according to a first embodiment.

FIG. 2 is an enlarged cross-sectional view of a part of the wiring substrate shown in FIG. 1.

FIG. 3 is a cross-sectional view showing one step in a manufacturing method of the wiring substrate shown in FIG. 1.

FIG. 4 is a cross-sectional view showing another step in the manufacturing method of the wiring substrate shown in FIG. 1.

FIG. 5 is a cross-sectional view showing still another step in the manufacturing method of the wiring substrate shown in FIG. 1.

FIG. 6 is a cross-sectional view showing still another step in the manufacturing method of the wiring substrate shown in FIG. 1.

FIG. 7 is a cross-sectional view showing still another step in the manufacturing method of the wiring substrate shown in FIG. 1.

FIG. 8 is a cross-sectional view showing still another step in the manufacturing method of the wiring substrate shown in FIG. 1.

FIG. 9 is a cross-sectional view showing still another step in the manufacturing method of the wiring substrate shown in FIG. 1.

FIG. 10 is a cross-sectional view showing still another step in the manufacturing method of the wiring substrate shown in FIG. 1.

FIG. 11 is a cross-sectional view showing still another step in the manufacturing method of the wiring substrate shown in FIG. 1.

FIG. 12 is an enlarged cross-sectional view of a part of a wiring substrate according to a second embodiment.

FIG. 13 is a cross-sectional view showing one step in a manufacturing method of the wiring substrate according to the second embodiment.

FIG. 14 is a cross-sectional view showing another step in the manufacturing method of the wiring substrate according to the second embodiment.

FIG. 15 is an enlarged cross-sectional view of a part of a wiring substrate according to a modification of the second embodiment.

### DETAILED DESCRIPTION

Hereinafter, embodiments of the present invention will be described with reference to the drawings. The embodiments described below embody any one of the above aspects more specifically. The matters described below can be incorporated into each of the above aspects alone or in combination.

In addition, the embodiments shown below describe examples of configurations for embodying a technical idea of the present invention, and the technical idea of the present invention is not limited by the materials, shapes, structures, etc., of the constituent members described below. Various changes can be made to the technical idea of the present invention within the technical scope defined by the claims.

Note that elements having the same or similar functions will be assigned the same reference numerals in the drawings referred to below, and redundant descriptions will be omitted. Furthermore, the drawings are schematic, and the relationship between the dimension in one direction and the dimension in another direction, the relationship between the dimension of a member and the dimension of another member, etc., may differ from the actual ones.

### <1> First Embodiment

A wiring substrate according to the first embodiment will be described.

### <1.1> Configuration of Wiring Substrate

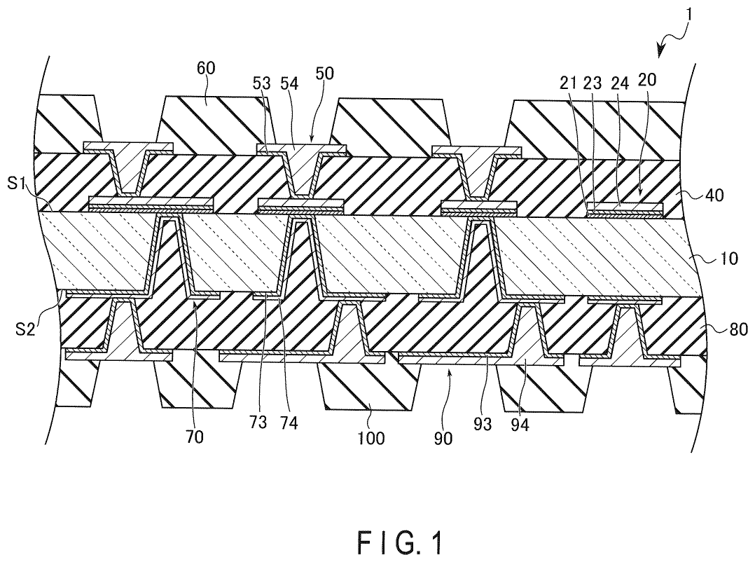

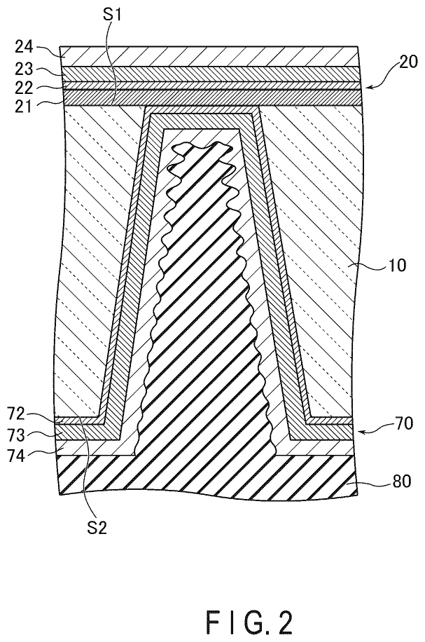

FIG. 1 is a cross-sectional view of the wiring substrate according to the first embodiment. FIG. 2 is an enlarged cross-sectional view of a part of the wiring substrate shown in FIG. 1.

A wiring substrate 1 shown in FIG. 1 is a glass core wiring substrate. According to one example, the wiring substrate 1 is a wiring substrate used as an interposer, that is, a glass interposer.

The wiring substrate 1 includes a glass substrate 10, a first conductor layer 20, an interlayer insulating film 40, a conductor layer 50, an insulating layer 60, a second conductor layer 70, an interlayer insulating film 80, a conductor layer 90, and an insulating layer 100.

The glass substrate 10 is, for example, non-alkali glass. The glass substrate 10 has a first surface S1 and a second surface S2 serving as a back surface of the first surface S1. The first surface S1 and the second surface S2 are parallel to each other. The thickness of the glass substrate 10 falls within a range of, for example, 25 μm or greater and 150 μm or smaller.

The glass substrate 10 is provided with one or more through holes each extending from the first surface S1 to the second surface S2. Herein, the glass substrate 10 is provided with a plurality of through holes. Each of the through holes tapers from the second surface S2 toward the first surface S1.

The first conductor layer 20 is a conductor pattern provided on the first surface S1. This conductor pattern includes a land portion and a wiring portion. The first conductor layer 20 is a first wiring layer.

The first conductor layer 20 has a multilayer structure. Specifically, the first conductor layer 20 includes a first copper layer 24 facing the first surface S1, and a hydrofluoric acid-resistant metal layer 21 interposed between the first copper layer 24 and the glass substrate 10. As shown in FIG. 2, the first conductor layer 20 further includes an adhesion layer 22 interposed between the hydrofluoric acid-resistant metal layer 21 and the first copper layer 24, and a seed layer 23 interposed between the adhesion layer 22 and the first copper layer 24.

The first conductor layer 20 covers an opening of the through hole on the first surface S1 side.

The hydrofluoric acid-resistant metal layer 21 is formed of a metal material that is more resistant to etching with hydrofluoric acid than the glass substrate 10. The hydrofluoric acid-resistant metal layer 21 is formed of, for example, a material obtained from the group consisting of chromium, nickel, and nickel-chromium alloy, for example. The thickness of the hydrofluoric acid-resistant metal layer 21 falls within a range of, for example, 10 nm or greater and 1000 nm or smaller.

The adhesion layer 22 and the seed layer 23 are laminated in this order on the hydrofluoric acid-resistant metal layer 21. For the adhesion layer 22 and the seed layer 23, materials exemplified for an adhesion layer 72 and a seed layer 73, which will be described later, can be used, respectively. The adhesion layer 22 and the seed layer 23 are provided in a case where the first copper layer 24 is formed by electrolytic plating. The adhesion layer 22 may be omitted. Moreover, in a case where the first copper layer 24 is formed using another method such as electroless plating or sputtering, both the adhesion layer 22 and the seed layer 23 may be omitted. The thickness of the first copper layer 24 falls within a range of, for example, 2 μm or greater and 20 μm or smaller.

The interlayer insulating film 40 covers the first surface S1 and has the first conductor layer 20 embedded therein. The interlayer insulating film 40 is provided with a through hole at a position of a land portion included in the first conductor layer 20. According to one example, the interlayer insulating film 40 is an insulating resin layer. As the insulating resin layer, a liquid resin or a film-like resin, which is a thermosetting resin filled with filler, is mainly used. It is preferable that the thermosetting resin include at least one type of material selected from epoxy resin, polyimide resin, and polyamide resin. It is preferable that the filler include a material such as silica, titanium oxide, urethane, etc.

The conductor layer 50 is a conductor pattern provided on the interlayer insulating film 40. This conductor pattern includes a pad portion provided on the main surface of the interlayer insulating film 40 and a via portion covering the side wall of the through hole provided in the interlayer insulating film 40. The pad portion is an external connection terminal. Each via portion connects a land portion included in the first conductor layer 20 to the pad portion.

The conductor layer 50 includes a seed layer 53 and a copper layer 54. The seed layer 53 and the copper layer 54 are laminated in this order on the interlayer insulating film 40. The conductor layer 50 may further include an adhesion layer between the interlayer insulating film 40 and the seed layer 53. For the adhesion layer and the seed layer 53 included in the conductor layer 50, materials exemplified for the adhesion layer 72 and the seed layer 73, which will be described later, can be used, respectively. The seed layer 53 may be omitted.

The insulating layer 60 at least partially covers the interlayer insulating film 40 and has the conductor layer 50 embedded therein. A through hole is provided in the insulating layer 60 at a position of the pad portion included in the conductor layer 50. The insulating layer 60 is formed of, for example, solder resist.

The second conductor layer 70 is a conductor pattern that includes a part that covers the second surface S2 of the glass substrate 10, a part that covers the side wall of the through hole provided in the glass substrate 10, and a part that is in contact with a part of the first conductor layer 20 which covers the through hole provided in the glass substrate 10. This conductor pattern includes a land portion, a wiring portion, and a via portion. A part of the second conductor layer 70 which covers the second surface S2 is a second wiring layer and includes a land portion and a wiring portion. The via portion consists of a part of the second conductor layer 70 which covers the side wall of the through hole provided in the glass substrate 10, and a part that is in contact with a part of the first conductor layer 20 which covers the through hole provided in the glass substrate 10.

The second conductor layer 70 has a multilayer structure. Specifically, the second conductor layer 70 includes the adhesion layer 72, the seed layer 73, and a second copper layer 74, as shown in FIG. 2. The adhesion layer 72, the seed layer 73, and the second copper layer 74 are laminated in this order on the glass substrate 10.

The adhesion layer 72 covers the side wall of the through hole provided in the glass substrate 10, the part of the first conductor layer 20 which covers the through hole provided in the glass substrate 10, and a region of the second surface S2 which surrounds the opening on the second surface S2 side of the through hole. The adhesion layer 72 is conformal to these surfaces.

The adhesion layer 72 increases the adhesion of the seed layer 73 with respect to the glass substrate 10. The adhesion layer 72 is preferably formed of one or more materials selected from the group consisting of titanium, chromium, and nickel, or an oxide thereof, and more preferably formed of titanium or titanium oxide.

The seed layer 73 is provided on the adhesion layer 72. The seed layer 73 is conformal to the adhesion layer 72. The seed layer 73 serves as a power supply layer in electrolytic plating. The seed layer 73 is appropriately selected from the group consisting of, for example, Cu, Ni, Al, Ti, Cr, Mo, W, Ta, Au, Ir, Ru, Pd, Pt, AlSi, AlSiCu, AlCu, NiFe, ITO, IZO, AZO, ZnO, PZT, TiN, and Cu₃N₄.

The second copper layer 74 is provided on the seed layer 73. The second copper layer 74 is conformal to the seed layer 73. The thickness of the second copper layer 74 falls within a range of, for example, 2 μm or greater and 20 μm or smaller.

The second copper layer 74 is different in surface roughness between its part provided in the through hole and its part provided on the second surface S2. Specifically, an arithmetic surface roughness Ra of the part of the second copper layer 74 provided in the through hole falls within a range of 150 nm or greater and 1000 nm or smaller, more specifically within a range of 150 nm or greater and 400 nm or smaller. Furthermore, the arithmetic surface roughness Ra of the part of the second copper layer 74 provided on the side wall of the through hole increases within the aforementioned range in a direction from the second surface S2 side to the first surface S1 side of the through hole. The arithmetic surface roughness Ra of the part of the second copper layer 74 provided on the second surface S2 is 100 nm or smaller. Note that the “arithmetic surface roughness Ra” is a surface quality parameter defined in JIS B0601:2001.

The interlayer insulating film 80 covers the second surface S2 and has the second conductor layer 70 embedded therein. The interlayer insulating film 80 is provided with a through hole at a position of a land portion included in the second conductor layer 70. According to one example, the interlayer insulating film 80 is an insulating resin layer. For the insulating resin layer included in the interlayer insulating film 80, materials exemplified for the insulating resin layer included in the interlayer insulating film 40 described above can be used.

The conductor layer 90 is a conductor pattern provided on the interlayer insulating film 80. This conductor pattern includes a pad portion provided on the main surface of the interlayer insulating film 80 and a via portion covering the side wall of the through hole provided in the interlayer insulating film 80. The pad portion is an external connection terminal. Each via portion connects the land portion included in the second conductor layer 70 to the pad portion.

The conductor layer 90 includes a seed layer 93 and a copper layer 94. The seed layer 93 and the copper layer 94 are laminated in this order on the interlayer insulating film 80. The conductor layer 90 may further include an adhesion layer between the interlayer insulating film 80 and the seed layer 93. For the adhesion layer and the seed layer 93 included in the conductor layer 90, materials exemplified for the adhesion layer 72 and the seed layer 73 can be used, respectively. The seed layer 93 may be omitted.

The insulating layer 100 at least partially covers the interlayer insulating film 80 and has the conductor layer 90 embedded therein. A through hole is provided in the insulating layer 100 at a position of the pad portion included in the conductor layer 90. The insulating layer 100 is formed of, for example, solder resist.

### <1.2> Manufacturing Method of Wiring Substrate

The wiring substrate 1 described above can be manufactured by, for example, a method described below.

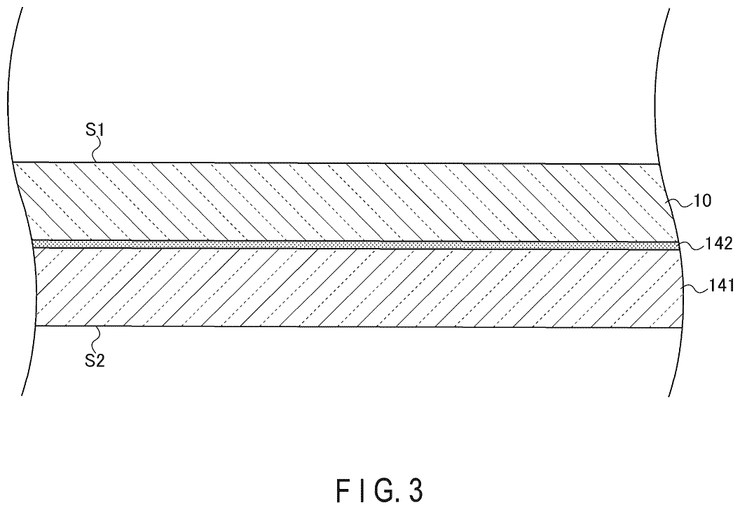

FIG. 3 to FIG. 11 are each a cross-sectional view showing a manufacturing method of the wiring substrate shown in FIG. 1.

### <1.2.1> First Step

First, as shown in FIG. 3, a support body 141 is bonded to the second surface S2 via a bonding layer 142. In order to bond the support body 141 to the glass substrate 10, for example, a laminator, a vacuum pressure press, a reduced pressure bonding machine, etc., can be used.

The bonding layer 142 is a bonding layer for temporarily fixing the support body 141 to the glass substrate 10. For the bonding layer 142, a resin or a functional group formed on the support body 141 is used. Examples of the resin include a resin that becomes peelable by generating heat, sublimating, or changing in quality by absorbing light such as UV light and a resin that becomes peelable by foaming due to heat. According to one example, the bonding layer 142 is a functional group formed on the second surface S2. Examples of the functional group used as the bonding layer 142 include, for example, a hydroxyl group.

Note that in FIG. 3 to FIG. 7, for convenience of description, the bonding layer 142 is illustrated in the form of a layer with a thickness. However, in a case where the functional group formed on the second surface S2 is used as the bonding layer 142, the thickness of the bonding layer 142 is negligibly small compared to the glass substrate 10 and the support body 141. Therefore, the bonding layer 142 can also be expressed as an interface between the glass substrate 10 and the support body 141. In such a case, the support body 141 can also be expressed as being directly bonded to the glass substrate 10.

The support body 141 is a first support body and is a carrier formed into a thin plate shape. From the viewpoint of adhesiveness, it is desirable that the support body 141 be formed of the same material as that of the glass substrate 10. That is, in a case where the glass substrate 10 is formed of non-alkali glass, it is preferable that the support body 141 also be formed of non-alkali glass. The thickness of the support body 141 may be set as appropriate depending on the thickness of the glass substrate 10. It is preferable that the thickness of the support body 141 fall within a range of 300 μm or greater and 1500 μm or smaller in consideration of the transportability of the glass substrate 10.

According to one example, Glass On Glass (GOG) manufactured by Nippon Electric Glass Co., Ltd. is used as a laminated structure including the glass substrate 10, the bonding layer 142, and the support body 141, which are bonded together. In such a case, the support body 141 is glass, and the bonding layer 142 includes a hydroxyl group and a plurality of functional groups.

### <1.2.2> Second Step

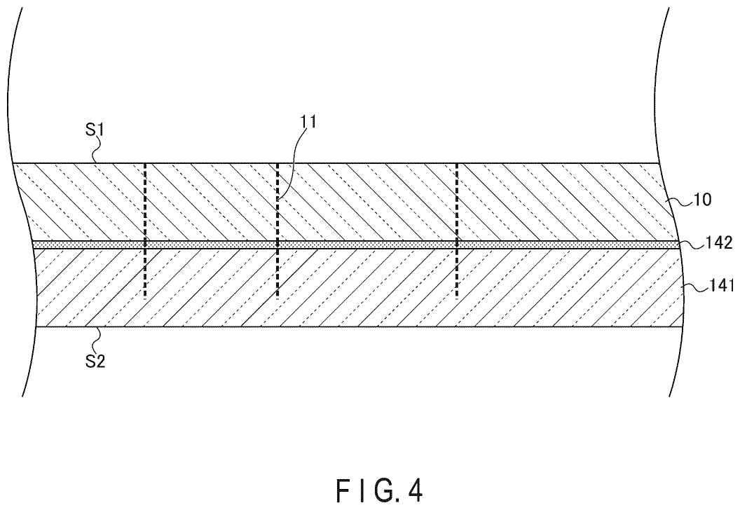

Next, one or more modified portions 11 are formed on the glass substrate 10 by irradiating the glass substrate 10 with laser light. The irradiation direction of the laser light may be a direction extending from the first surface S1 to the second surface S2, or a direction extending from the second surface S2 to the first surface S1. The modified portion 11 is, for example, a part which is heated by laser irradiation to have a difference in crystallinity, etc., from a portion that has not been irradiated with laser light. The modified portion 11 is formed at a position corresponding to a through hole to be formed in the glass substrate 10. For example, the modified portion 11 extends in a direction intersecting the first surface S1 and the second surface S2. As shown in FIG. 4, in a case where the laser light is irradiated from the first surface S1 toward the second surface S2, the modified portion 11 may be formed so as to reach the bonding layer 142 and the support body 141.

The wavelength of the laser light used herein is 535 nm or smaller. The preferable wavelength of the laser light is 355 nm or greater and 535 nm or smaller. In a case of the wavelength of the laser light being set to be smaller than 355 nm, it is difficult to obtain sufficient laser output, thereby leading to a risk that it may become difficult to obtain stable laser modification. On the other hand, in a case of the wavelength of the laser light being set to be greater than 535 nm, the irradiation spot becomes large, thereby making it difficult to modify a small area with a laser. Furthermore, due to the influence of heat, microcracks occur, so that the glass substrate 10 becomes easily broken.

In a case of using a pulsed laser, it is desirable that the laser pulse width fall within a range of picoseconds to femtoseconds. In a case where the laser pulse width is a nanosecond or longer, it becomes difficult to control the amount of energy per pulse and microcracks occur, so that the glass substrate 10 becomes easily broken.

A preferable value for the energy of the laser pulse is selected in accordance with the composition of the glass and the type of laser modification to be caused, and it is preferable that such a value fall within a range of 5 μJ or greater and 150 μJ or smaller. By increasing the energy of the laser pulse, it becomes possible to increase the length of the modified portion 11 in proportion to the increase in the energy.

### <1.2.3> Third Step

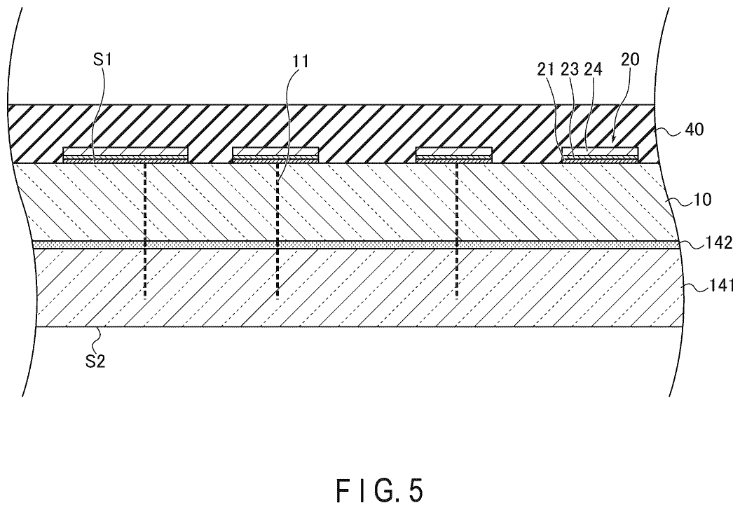

Next, as shown in FIG. 5, the first conductor layer 20 is formed on the first surface S1 so as to cover the modified portion 11.

For example, first, the hydrofluoric acid-resistant metal layer 21 and the seed layer 23 are formed in this order on the first surface S1. Herein, each of the hydrofluoric acid-resistant metal layer 21 and the seed layer 23 is formed as a continuous film. The hydrofluoric acid-resistant metal layer 21 is formed by, for example, sputtering. The seed layer 23 is formed by, for example, sputtering or electroless plating. Prior to the formation of the seed layer 23, an adhesion layer 22 shown in FIG. 2 may be formed on the hydrofluoric acid-resistant metal layer 21. The adhesion layer 22 is formed as a continuous film by, for example, sputtering or electroless plating. The formation of the adhesion layer 22 improves the adhesion between the hydrofluoric acid-resistant metal layer 21 and the seed layer 23.

Next, a mask pattern formed of an insulator and having an opening at a position corresponding to the first copper layer 24 is formed on the seed layer 23. The mask pattern is formed by, for example, providing a photoresist layer on the seed layer 23 and performing pattern exposure and development on the aforementioned photoresist layer. According to one example, a dry photoresist RD1225 manufactured by Showa Denko Materials Co., Ltd. is laminated on the seed layer 23, and a mask pattern formed of a resin is obtained by sequentially performing pattern exposure and development on the aforementioned dry photoresist.

Subsequently, electrolytic copper plating is performed using the seed layer 23 as a power supply layer. In this manner, copper is deposited on the seed layer 23 at a position of the opening portion of the mask pattern, thereby obtaining the first copper layer 24 shown in FIG. 5.

Thereafter, the mask pattern is removed. For example, a dry film resist is dissolved and peeled off. Next, the entire surface on the first copper layer 24 side of a composite including the first copper layer 24 and the glass substrate 10 is etched until the exposed portion of the seed layer 23 is removed. Furthermore, in a case where the adhesion layer 22 is present between the seed layer 23 and the hydrofluoric acid-resistant metal layer 21, the entire surface on the first copper layer 24 side of the composite is further etched until a part of the adhesion layer 22 which is exposed by removing the exposed portion of the seed layer 23 is also removed. Then, the entire surface on the first copper layer 24 side of the composite including the first copper layer 24 and the glass substrate 10 is etched until the exposed portion of the hydrofluoric acid-resistant metal layer 21 is removed.

In the manner described above, the first conductor layer 20 shown in FIG. 5 is obtained. Note that, as described above, the first conductor layer 20 includes the land portion and the wiring portion.

Thereafter, the interlayer insulating film 40 is provided on the surface of the glass substrate 10, on which the first conductor layer 20 is provided. In a case of a liquid resin, the interlayer insulating film 40 is formed by spin coating. In a case of a film-like resin, the interlayer insulating film 40 is formed by heating and pressurization under vacuum using a vacuum laminator. According to one example, ABF-GXT31 (32.5 μm thickness), which is an insulating resin film manufactured by Ajinomoto Fine Techno Co., Ltd. is laminated as the interlayer insulating film 40 on the aforementioned surface, and is pre-cured.

### <1.2.4> Fourth Step

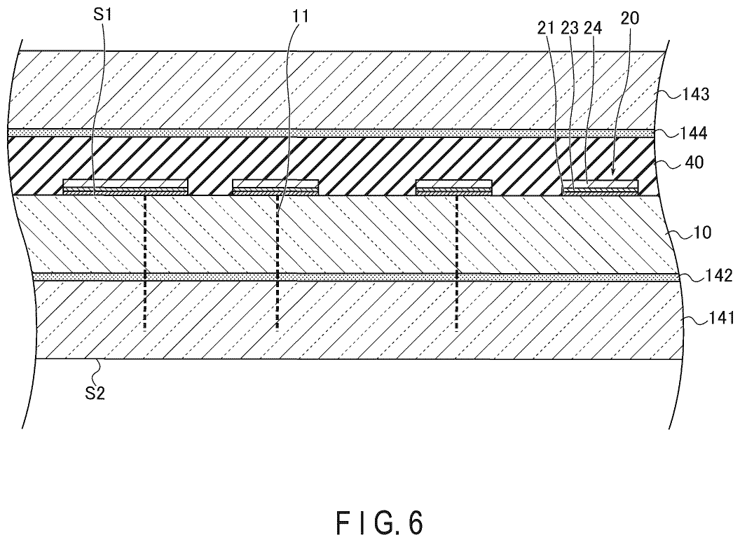

Next, as shown in FIG. 6, a composite including the glass substrate 10 and the interlayer insulating film 40 is supported by a support body 143. Herein, the composite and the support body 143 are bonded together via a bonding layer 144 so that the interlayer insulating film 40 of the composite faces the support body 143.

For the bonding layer 144, a resin or a functional group which is formed on the support body 143 is used. Examples of the resin include a resin that becomes peelable by generating heat, sublimating, or changing in quality by absorbing light such as UV light, and a resin that becomes peelable by foaming due to heat. It is preferable that the bonding layer 144 be formed of a different material from that of the bonding layer 142. According to one example, LivaAlpha (registered trademark) manufactured by Nitto Denko Corporation is used as the bonding layer 144.

The support body 143 is a second support body and is a carrier formed into a thin plate shape. It is desirable that the support body 143 be formed of the same material as that of the glass substrate 10. That is, in a case where the glass substrate 10 is formed of non-alkali glass, it is preferable that the support body 143 also be formed of non-alkali glass. The thickness of the support body 143 may be set as appropriate depending on the thickness of the glass substrate 10. It is preferable that the thickness of the support body 143 fall within a range of 300 μm or greater and 1500 μm or smaller in consideration of the transportability of the glass substrate 10.

### <1.2.5> Fifth Step

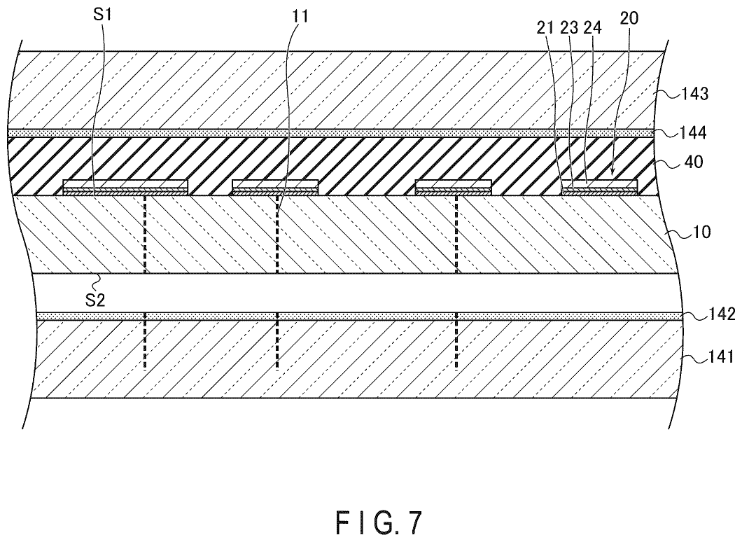

Next, as shown in FIG. 7, the bonding layer 142 and the support body 141 are separated from the glass substrate 10. In the separation of the bonding layer 142 and the support body 141 from the glass substrate 10, an appropriate peeling method is selected from UV light irradiation, heating processing, physical peeling, etc., depending on the material used for the bonding layer 142. In a case where a residual of the bonding layer 142 remains on glass substrate 10 after peeling processing of the bonding layer 142 and the support body 141, plasma cleaning, ultrasonic cleaning, water cleaning, solvent cleaning using alcohol, etc., may be performed.

### <1.2.6> Sixth Step

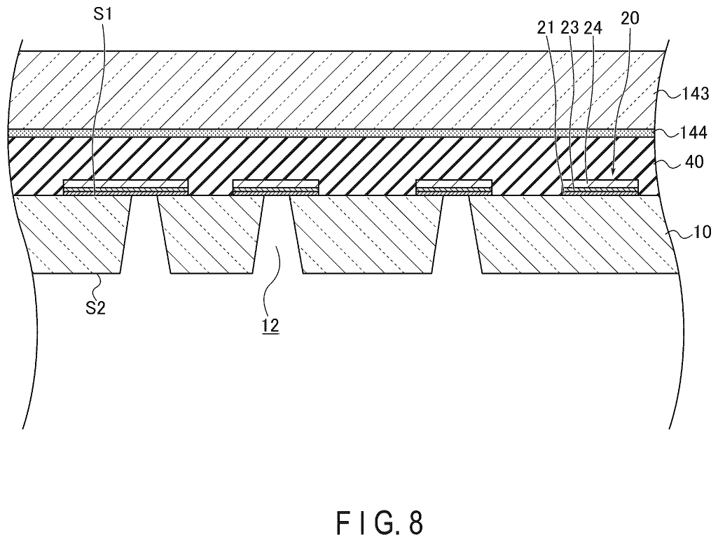

Next, the second surface S2 of the glass substrate 10 from which the bonding layer 142 and the support body 141 have been peeled off is etched with an etching solution including hydrogen fluoride. As a result, as shown in FIG. 8, the second surface S2 is recessed, and through holes 12 are formed at the positions of the modified portions 11, respectively. In the glass substrate 10, the modified portion 11 is higher in etching rate than the other portions. Therefore, thinning of the glass substrate 10 and formation of the through holes 12 can be achieved simultaneously by the etching processing described above.

The amount of etching by the etching processing is appropriately set depending on the thickness of the glass substrate 10. For example, in a case where the thickness of the glass substrate 10 before etching processing is 200 μm, it is preferable that the amount of etching of the glass substrate 10 fall within a range of 50 μm or greater and 175 μm or smaller. This enables the thickness of the glass substrate 10 after the etching processing to fall within a range of 25 μm or greater and 150 μm or smaller.

In addition, in the etching processing, the hydrofluoric acid-resistant metal layer 21 plays a role as an etching stopper film. Furthermore, in FIG. 8, the through holes 12 obtained by the aforementioned etching each have a truncated conical shape in which the diameter (or cross-sectional area) on the second surface S2 side is larger than the diameter (or cross-sectional area) on the first surface S1 side.

The etching solution including hydrogen fluoride is, for example, a hydrogen fluoride aqueous solution. The etching solution can further include one or more types of inorganic acid, selected from the group consisting of nitric acid, hydrochloric acid, and sulfuric acid.

The hydrogen fluoride concentration of the etching solution falls within a range of, for example, 1.0% by mass or greater and 6.0% by mass or smaller, preferably within a range of 2.0% by mass or greater and 5.0% by mass or smaller. The inorganic acid concentration falls within a range of, for example, 1.0% by mass or greater and 20.0% by mass or smaller, preferably within a range of 3.0% by mass or greater and 16.0% by mass or smaller. It is desirable that the etching processing be performed at an etching rate of 1.0 μm/min or smaller using an etching solution in which the concentration of each component is set within a range described above. It is desirable that the temperature of etching solution for the etching processing fall within a range of 10° C. or greater and 40° C. or smaller.

### <1.2.7> Seventh Step

Thereafter, an adhesion layer 72 shown in FIG. 2 is formed. Herein, the adhesion layer 72 is formed as a continuous film that covers the side wall of the through hole 12 and the second surface S2. The adhesion layer 72 is formed as a continuous film by, for example, sputtering or electroless plating.

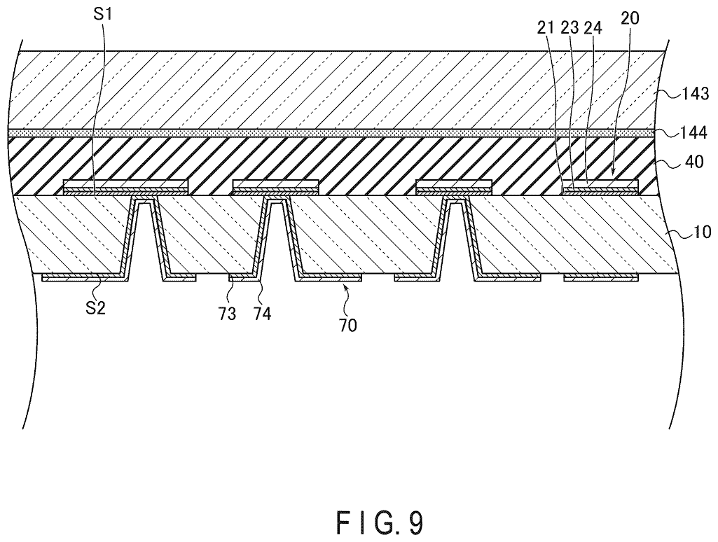

Next, the seed layer 73 shown in FIG. 9 is formed on the adhesion layer 72. The seed layer 73 is formed as a continuous film by, for example, sputtering or electroless plating.

Next, as shown in FIG. 9, the second copper layer 74 is formed on the seed layer 73.

For example, first, a mask pattern formed of an insulator and having an opening at a position corresponding to the second copper layer 74 is formed on the seed layer 73. The mask pattern is formed by, for example, providing a photoresist layer on the seed layer 73 and performing pattern exposure and development on the aforementioned photoresist layer. According to one example, a dry photoresist RD1225 manufactured by Showa Denko Materials Co., Ltd. is laminated on the seed layer 73, and a mask pattern formed of a resin is obtained by sequentially performing pattern exposure and development on the aforementioned dry photoresist.

Subsequently, electrolytic copper plating is performed using the seed layer 73 as a power supply layer. In this manner, copper is deposited on the seed layer 73 at a position of the opening portion of the mask pattern, thereby obtaining the second copper layer 74 shown in FIG. 9.

The aforementioned electrolytic copper plating is performed using, for example, an insoluble anode electrode and using a copper sulfate electrolytic Cu plating solution in an electrolytic plating apparatus of a jet agitation type under the condition of a current density of 1.0 ASD to 2.0 ASD and a jet flow rate of 10 L/(min·m²) to 30 L/(min·m²). The copper sulfate electrolytic Cu plating solution includes 80 g/L to 200 g/L of CuSO₄·5H₂O, 20 g/L to 200 g/L of H₂SO₄, and 3 mg/L to 6 mg/L of accelerator as an additive, 0.1 mg/L to 5 mg/L of inhibitor, 5 ppm to 30 ppm of HCl, and 0.5 mg/L to 2 mg/L of leveler. Furthermore, the distance from the nozzle from which the plating solution is ejected to the glass substrate 10 is 50 mm to 150 mm. By performing the electrolytic copper plating under such a condition, a difference occurs in the circulation speed of the plating solution between the inside of the through hole 12 and the second surface S2, resulting in a finish in which the crystallinity and roughness of the plating differ between the inside of the through hole 12 and the second surface S2. Specifically, the arithmetic surface roughness Ra of the second copper layer 74 provided on the side wall of the through hole 12 becomes larger than the arithmetic surface roughness Ra of the second copper layer 74 provided on the second surface S2. Furthermore, the arithmetic surface roughness Ra of the part of the second copper layer 74 provided on the side wall of the through hole increases in a direction from the second surface S2 side to the first surface S1 side of the through hole.

Thereafter, the mask pattern is removed. For example, a dry film resist is dissolved and peeled off. Next, the exposed portion of the seed layer 73 is removed by etching the entire surface on the second copper layer 74 side of the composite including the second copper layer 74 and the glass substrate 10. Subsequently, the entire surface on the second copper layer 74 side of the composite is further etched until a part of the adhesion layer 72 which is exposed by removing the exposed portion of the seed layer 73 is removed.

In the manner described above, the second conductor layer 70 shown in FIG. 9 is obtained. Note that, as described above, the second conductor layer 70 includes the land portion and the wiring portion. Furthermore, the arithmetic surface roughness Ra of the second copper layer 74 provided on the side wall of the through hole 12 is 150 nm or greater and 1000 nm or smaller. Moreover, the arithmetic surface roughness Ra of the second copper layer 74 provided on the second surface S2 is 100 nm or smaller.

### <1.2.8> Eighth Step

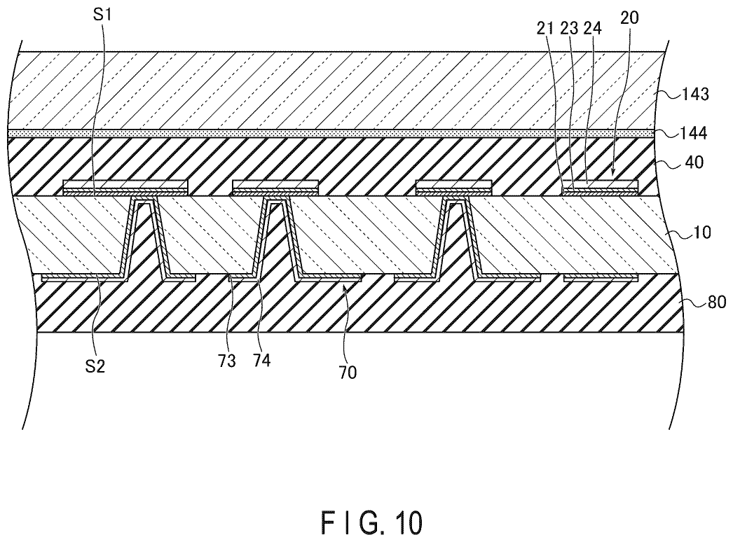

Next, as shown in FIG. 10, an interlayer insulating film 80 is provided on the surface on the second conductor layer 70 side of the composite including the second conductor layer 70 and the glass substrate 10. In a case of a liquid resin, the interlayer insulating film 80 is formed by spin coating. In a case of a film-like resin, the interlayer insulating film 80 is formed by heating and pressurization under vacuum using a vacuum laminator. According to one example, ABF-GXT31 (32.5 μm thickness), which is an insulating resin film manufactured by Ajinomoto Fine Techno Co., Ltd. is laminated as the interlayer insulating film 80 on the aforementioned surface, and is pre-cured.

### <1.2.9> Ninth Step

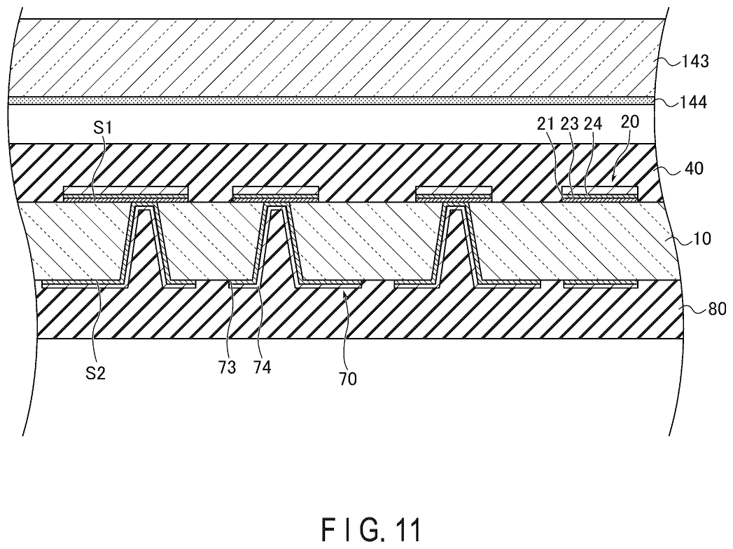

Next, as shown in FIG. 11, the bonding layer 144 and the support body 143 are separated from the glass substrate 10. In the separation of the bonding layer 144 and the support body 143 from the glass substrate 10, an appropriate peeling method is selected from UV light irradiation, heating processing, physical peeling, etc., depending on the material used for the bonding layer 144. In a case where a residual of the bonding layer 144 remains on glass substrate 10 after peeling processing of the bonding layer 144 and the support body 143, plasma cleaning, ultrasonic cleaning, water cleaning, solvent cleaning using alcohol, etc., may be performed.

### <1.2.10> Tenth Step

Next, blind vias are formed in the interlayer insulating film 40 by laser processing. Thereafter, desmear processing is performed to remove the residue generated through the laser processing. Note that the laser used to form each blind via may be different from the laser used to form the modified portion 11. For example, it is preferable that a pulsed laser such as a carbon dioxide laser or a UV-YAG laser be used to form the blind via. In a case of using a pulsed laser, it is preferable that the laser pulse width fall within a range of microseconds.

Thereafter, the seed layer 53 is formed by sputtering or electroless plating. Herein, the seed layer 53 is formed to cover the upper surface of the interlayer insulating film 40, the side walls of the through holes provided therein, and parts of the first conductor layer 20 which are exposed at the positions of these through holes.

Next, a mask pattern formed of an insulator and having an opening at a position corresponding to the copper layer 54 is formed on the seed layer 53. The mask pattern is formed by, for example, providing a photoresist layer on the seed layer 53 and performing pattern exposure and development on the aforementioned photoresist layer. According to one example, an RD1225 manufactured by Showa Denko Materials Co., Ltd. is laminated on the seed layer 53, and a mask pattern formed of a resin is obtained by sequentially performing pattern exposure and development on the aforementioned dry film resist.

Subsequently, electrolytic copper plating is performed using the seed layer 53 as a power supply layer. In this manner, copper is deposited on the seed layer 53 at a position of the opening portion of the mask pattern, thereby obtaining the copper layer 54 shown in FIG. 1.

Thereafter, the mask pattern is removed. For example, a dry film resist is dissolved and peeled off. Next, the entire surface on the copper layer 54 side of a composite including the copper layer 54 and the glass substrate 10 is etched until the exposed portion of the seed layer 53 is removed. In the manner described above, the conductor layer 50 is obtained.

Next, an insulating layer 60 shown in FIG. 1 is provided on the interlayer insulating film 40. For example, a solder resist is provided on the interlayer insulating film 40 and patterned using a photolithography method, etc.

Similar processing is performed on the opposite side to obtain the conductor layer 90 and the insulating layer 100.

In the manner described above, the wiring substrate 1 shown in FIG. 1 is obtained.

### <1.3> Advantageous Effect of First Embodiment

In order to ensure adhesion between the copper layer and the resin, it is preferable that the surface roughness of the copper layer be large. However, in a case where the surface roughness of the copper layer is increased, the transmission of high frequency signals may be affected.

According to the first embodiment, the second copper layer 74 is provided in electrolytic copper plating in which the jet amount of the plating solution is suppressed to 10 L/(min·m²) to 30 L/(min·m²). By this, the surface roughness of the part of the second copper layer 74 which is provided inside the through hole 12 becomes greater than the surface roughness of the part of the second copper layer 74 which is provided on the second surface S2. This can ensure the adhesion between the second copper layer 74 and the interlayer insulating film 80 in the through hole 12. Furthermore, since the part with high surface roughness is limited to the inside of the through hole 12, the influence on the transmission of high frequency signals is suppressed as compared to a case in which the surface roughness of the entire second copper layer 74 including the part provided on the second surface S2 is made large. Therefore, according to the manufacturing method described above, high reliability can be achieved while suppressing the influence on the transmission of high frequency signals.

Furthermore, according to the first embodiment, by changing the conditions for the electrolytic copper plating from those in a case in which the surface roughness of the second copper layer 74 is not made different between the upper part of the second surface S2 and the inside of the through hole 12, the second copper layer 74 and the second copper layer 74 which are different in surface roughness can be respectively provided on the side wall of the through hole 12 and the second surface S2. That is, with respect to a case in which the surface roughness of the second copper layer 74 is not made different between the upper part of the second surface S2 and the inside of the through hole 12, high reliability can be achieved without requiring any additional steps.

### <2> Second Embodiment

The second embodiment of the present invention differs from the first embodiment in that a corrosion prevention film is used to ensure adhesion between the copper layer provided on the side wall of the through hole and the resin. The differences from the first embodiment will be described with reference to the second embodiment.

### <2.1> Configuration of Wiring Substrate

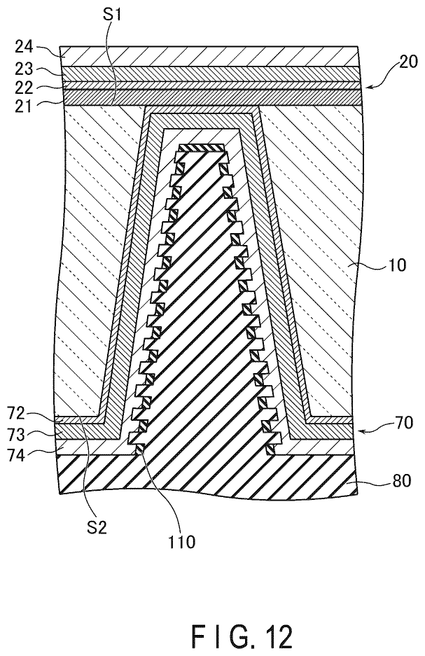

FIG. 12 is an enlarged cross-sectional view of a part of a wiring substrate according to a second embodiment.

The wiring substrate 1 further includes a corrosion prevention film 110.

The second copper layer 74 is different in surface roughness between its part provided on the side wall of the through hole provided in the glass substrate 10 and its parts provided on the second surface S2 and provided on the first surface S1 side of the through hole provided in the glass substrate 10. Specifically, the arithmetic surface roughness Ra of the part of the second copper layer 74 provided on the side wall of the through hole falls within a range of 150 nm or greater and 1000 nm or smaller, more specifically, 300 nm or greater and 1000 nm or smaller. Furthermore, the arithmetic surface roughness Ra of the part of the second copper layer 74 provided on the side wall of the through hole increases within the aforementioned range in a direction from the first surface S1 side to the second surface S2 side of the through hole. With respect to the second copper layer 74, the arithmetic surface roughness Ra of its part provided on the second surface S2 and its part provided on the first surface S1 side of the through hole provided on the glass substrate 10 is 100 nm or smaller.

The second copper layer 74 has a plurality of convex portions on the side wall of the through hole. The convex portions are scattered across the entire side wall. The film thickness of the second copper layer 74 at the plurality of convex portions is greater than the film thickness of the second copper layer 74 in a part other than the convex portions on the side wall of the through hole. The convex portions of the second copper layer 74 are not provided on the surface on the first surface S1 side.

The corrosion prevention film 110 is provided inside the through hole and on the second copper layer 74. A part of the corrosion prevention film 110 covering the surface on the first surface S1 side of the through hole is provided as a continuous film. A part of the corrosion prevention film 110 provided on the side wall of the through hole is scattered on the convex portion of the second copper layer 74. In other words, the corrosion prevention film 110 has its opening in the side wall of the through hole except at the convex portion of the second copper layer 74. That is, the corrosion prevention film 110 has a discontinuous portion in the side wall portion of the through hole. The corrosion prevention film 110 includes an inorganic material such as SiN, SiO, etc.

The interlayer insulating film 80 covers the second surface S2 and has the second conductor layer 70 and the corrosion prevention film 110 embedded therein. The interlayer insulating film 80 is provided with a through hole at the position of the land portion included in the second conductor layer 70. According to one example, the interlayer insulating film 80 is an insulating resin layer. For the insulating resin layer included in the interlayer insulating film 80, materials exemplified for the insulating resin layer included in the interlayer insulating film 40 described above can be used.

The other configurations are the same as those of the first embodiment.

### <2.2> Manufacturing Method of Wiring Substrate

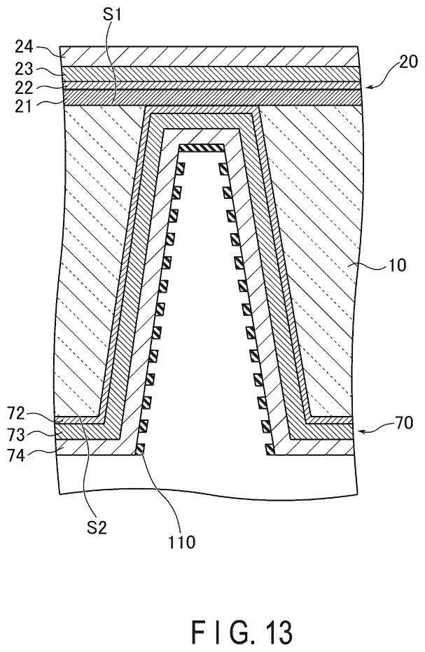

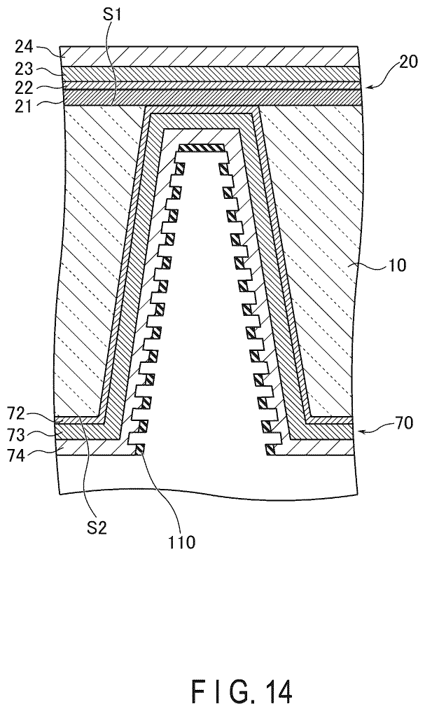

FIG. 13 is a cross-sectional view showing one step in a manufacturing method of the wiring substrate according to the second embodiment. FIG. 14 is a cross-sectional view showing another step in the manufacturing method of the wiring substrate according to the second embodiment.

The manufacturing method according to the second embodiment is similar to the manufacturing method described with reference to FIG. 1 to FIG. 11, except that the eleventh step, the twelfth step, and the thirteenth step are performed instead of the seventh step, as will be described below.

### <2.2.1> First to Sixth Steps

First, the first step to the sixth step are sequentially performed. Accordingly, the structure shown in FIG. 8 is obtained.

### <2.2.2> Eleventh Step

Thereafter, an adhesion layer 72 shown in FIG. 2 is formed. Herein, the adhesion layer 72 is formed as a continuous film that covers the side wall of the through hole 12 and the second surface S2. The adhesion layer 72 is formed as a continuous film by, for example, sputtering or electroless plating.

Next, the seed layer 73 shown in FIG. 9 is formed on the adhesion layer 72. The seed layer 73 is formed as a continuous film by, for example, sputtering or electroless plating.

Next, as shown in FIG. 9, the second copper layer 74 is formed on the seed layer 73.

For example, first, a mask pattern formed of an insulator and having an opening at a position corresponding to the second copper layer 74 is formed on the seed layer 73. The mask pattern is formed by, for example, providing a photoresist layer on the seed layer 73 and performing pattern exposure and development on the aforementioned photoresist layer. According to one example, a dry photoresist RD1225 manufactured by Showa Denko Materials Co., Ltd. is laminated on the seed layer 73, and a mask pattern formed of a resin is obtained by sequentially performing pattern exposure and development on the aforementioned dry photoresist.

Subsequently, electrolytic copper plating is performed using the seed layer 73 as a power supply layer. In this manner, copper is deposited on the seed layer 73 at a position of the opening portion of the mask pattern, thereby obtaining the second copper layer 74 shown in FIG. 9.

This electrolytic copper plating does not require control of the surface roughness of the second copper layer 74 provided on the side wall of the through hole, and it suffices to select a method that provides excellent productivity from among methods by which the arithmetic surface roughness Ra of the second copper layer 74 provided on the second surface S2 becomes 100 nm or smaller.

Thereafter, the mask pattern is removed. For example, a dry film resist is dissolved and peeled off.

### <2.2.3> Twelfth Step

Next, as shown in FIG. 13, the corrosion prevention film 110 is formed inside the through hole.

For example, first, a mask pattern with an opening at a position corresponding to the through hole is formed on the second surface S2. The mask pattern is formed by, for example, providing a photoresist layer on the second surface S2 and performing pattern exposure and development on the aforementioned photoresist layer.

Next, the corrosion prevention film 110 shown in FIG. 13 is formed. The corrosion prevention film 110 is formed so as to have a thickness of approximately 10 nm to 50 nm by, for example, plasma CVD or sputtering. The corrosion prevention film 110 is formed so as to include the discontinuous portion. More specifically, the corrosion prevention film 110 exhibits a state on the side wall of the through hole in which a part formed into a film and a part not formed into a film are mixed.

Thereafter, the mask pattern is removed.

In this manner, the corrosion prevention film 110 shown in FIG. 13 is obtained. In this manner, by forming an inorganic material into an extremely thin film through dry processing, a corrosion prevention film 110 which is an inorganic film having at least one or more opening portions can be formed.

### <2.2.4> Thirteenth Step

Next, the exposed portion of the seed layer 73 is removed by etching the entire surface on the second copper layer 74 side of the composite including the second copper layer 74, the corrosion prevention film 110, and the glass substrate 10. Subsequently, the entire surface on the second copper layer 74 side of the composite is further etched until a part of the adhesion layer 72 which is exposed by removing the exposed portion of the seed layer 73 is removed.

In a case where the seed layer 73 uses Cu, the second copper layer 74 is also etched at the same time by this etching. At this time, etching is suppressed in the part of the second copper layer 74 which is covered with the corrosion prevention film 110. This causes the part of the second copper layer 74 which is covered with the corrosion prevention film 110 to be a convex portion that is greater in film thickness than the part of the second copper layer 74 which is not covered with the corrosion prevention film 110. Accordingly, the surface of the second copper layer 74 provided on the side wall of the through hole 12 becomes rough. In the manner described above, the second copper layer 74 shown in FIG. 14 is obtained. The arithmetic surface roughness Ra of the second copper layer 74 provided on the side wall of the through hole 12 is 150 nm or greater and 1000 nm or smaller.

In a case where the seed layer 73 does not use Cu, the processing with a Cu etching solution may be performed either before or after removal of the seed layer 73. Using an etching solution of a sulfuric acid-hydrogen peroxide system as the Cu etching solution enables selective etching of a part of the second copper layer 74 on the side wall of the through hole 12, the part being not covered with the corrosion prevention film 110.

### <2.2.5> Eighth to Tenth Steps

Furthermore, the eighth step to the tenth step are sequentially performed on the composite including the second conductor layer 70 and the glass substrate 10. Accordingly, the wiring substrate 1 shown in FIG. 12 is obtained.

### <2.3> Advantageous Effect of Second Embodiment

According to the second embodiment, the corrosion prevention film 110 is formed on the second copper layer 74 by dry processing so as to have an extremely thin thickness of about 10 to 50 nm, and in this manner, the corrosion prevention film 110 is formed so as to be discontinuously scattered on the side wall of the through hole 12. Through subsequent etching processing, a part of the second copper layer 74 on the side wall of the through hole 12 which is not covered with the corrosion prevention film 110 is selectively etched. By this, the surface roughness of the part of the second copper layer 74 which is provided on the side wall of the through hole 12 becomes greater than the surface roughness of the part of the second copper layer 74 which is provided on the second surface S2. This can ensure, on the side wall of the through hole 12, the adhesion between the second copper layer 74 and the interlayer insulating film 80. Furthermore, since the part with high surface roughness is limited to the side wall of the through hole 12, the influence on the transmission of high frequency signals is suppressed as compared to a case in which the surface roughness of the entire second copper layer 74 including the part provided on the second surface S2 is made large. Therefore, according to the manufacturing method described above, high reliability can be achieved while suppressing the influence on the transmission of high frequency signals.

Furthermore, according to the second embodiment, the surface roughness of the second copper layer 74 is increased depending on whether the etching is performed or not. Accordingly, the arithmetic surface roughness Ra can be increased up to a value close to 1000 nm in a range of 150 nm or greater and 1000 nm or smaller, so that a wiring substrate with more superior reliability can be provided.

### <2.4> Modification

The wiring substrate according to the second embodiment described above can be modified in various ways.

### <2.4.1> Forming Method of Corrosion Prevention Film

For example, the corrosion prevention film 110 may be formed by the fourteenth step described below, instead of the twelfth step.

### <2.2.6> Fourteenth Step

Next, as shown in FIG. 13, the corrosion prevention film 110 is formed inside the through hole.

For example, first, a corrosion prevention film 110 is formed on the second surface S2 and inside the through hole. The corrosion prevention film 110 is formed so as to have a thickness of approximately 100 nm to 1000 nm by, for example, plasma CVD or sputtering.

Next, the entire second surface S2 is dry-etched to remove the corrosion prevention film 110 formed on the second surface S2. In dry etching with high linearity, etching of the corrosion prevention film 110 formed on the side wall of the through hole does not proceed easily. This enables the corrosion prevention film 110, which is an inorganic film having a large number of openings on the side wall of each through hole, to remain after the corrosion prevention film 110 on the second surface S2 is sufficiently removed.

In this manner, the corrosion prevention film 110 shown in FIG. 13 is obtained.

### <2.4.2> Removal of Corrosion Prevention Film

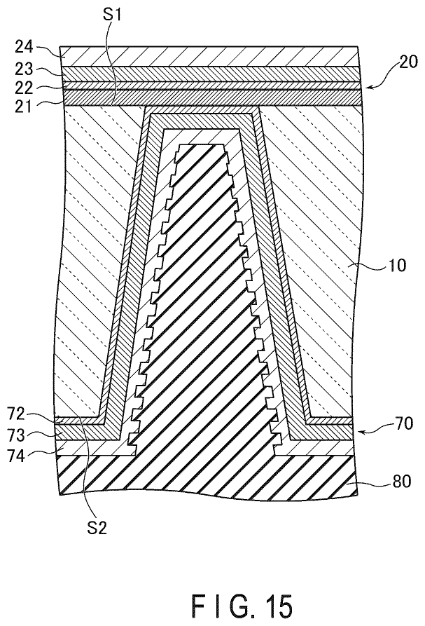

For example, the corrosion prevention film 110 may be removed after the thirteenth step is completed. FIG. 15 is an enlarged cross-sectional view of a part of a wiring substrate according to a modification of the second embodiment. As described above, even in a case where the corrosion prevention film is removed, a wiring substrate with excellent reliability can be provided.

### EXAMPLES

Hereinafter, tests carried out in relation to the present invention will be described.

### Example 1

The wiring substrate 1 described with reference to FIG. 1 and FIG. 2 was manufactured. The wiring substrate 1 was measured in terms of transmission loss S21 at 30 GHz in the microstrip line on the wiring substrate 1. Furthermore, a temperature cycle test was performed in which a heat load was repeatedly applied within a range of −55° C. to 125° C., and the presence or absence of breaks in a daisy chain of a through electrode was confirmed.

### Example 2

The wiring substrate 1 described with reference to FIG. 12 was manufactured. The aforementioned wiring substrate 1 was also measured in terms of the transmission loss S21 and was confirmed in terms of the presence or absence of breaks in a temperature cycle test by the same method as in Example 1.

### Comparative Example 1

A wiring substrate similar to that manufactured in Example 1 was manufactured, except that the arithmetic surface roughness Ra of the second copper layer 74 provided on the side wall of the through hole and the arithmetic surface roughness Ra of the second copper layer 74 provided on the second surface S2 were both set to 100 nm or smaller. The aforementioned wiring substrate was also measured in terms of the transmission loss S21 and was confirmed in terms of the presence or absence of breaks in a temperature cycle test by the same method as in Example 1.

### Comparative Example 2

A wiring substrate similar to that manufactured in Example 1 was manufactured, except that the arithmetic surface roughness Ra of the second copper layer 74 provided on the side wall of the through hole and the arithmetic surface roughness Ra of the second copper layer 74 provided on the second surface S2 were both set to 150 nm or greater and 1000 nm or smaller. The aforementioned wiring substrate was also measured in terms of the transmission loss S21 and was confirmed in terms of the presence or absence of breaks in a temperature cycle test by the same method as in Example 1.

### (Result)

The results are shown in Table 1 below.

TABLE 1

| | Ra of | Ra of | Corrosion | Transmission | Temperature cycle test | | |
|---|---|---|---|---|---|---|---|
| | through | second | prevention | loss | 1000 | 1500 | 2000 |
| | hole | surface | film | S21 | cycles | cycles | cycles |
| Example 1 | 187 nm | 87 nm | Absent | 0.81 | ∘ | ∘ | x |
| Example 2 | 823 nm | 76 nm | Present | 0.82 | ∘ | ∘ | ∘ |
| Comparative | 76 nm | 77 nm | Absent | 0.82 | ∘ | x | x |
| example 1 | | | | | | | |
| Comparative | 412 nm | 412 nm | Absent | 1.21 | ∘ | ∘ | ∘ |
| example 2 | | | | | | | |

In Table 1, “o” indicates that a daisy chain was not broken, and “x” indicates that the daisy chain was broken.

As shown in Table 1, Examples 1 and 2 were able to suppress the transmission loss S21 compared to Comparative Example 2. Furthermore, Examples 1 and 2 were able to suppress the decrease in reliability compared to Comparative Example 1.

### REFERENCE SIGNS LIST

1 . . . wiring substrate, 10 . . . glass substrate, 11 . . . modified portion, 12 . . . through hole, 20 . . . first conductor layer, 21 . . . hydrofluoric acid-resistant metal layer, 22 . . . adhesion layer, 23 . . . seed layer, 24 . . . first copper layer, 40 . . . interlayer insulating film, 50 . . . conductor layer, 53 . . . seed layer, 54 . . . copper layer, 60 . . . insulating layer, 70 . . . second conductor layer, 70 . . . conductor layer, 72 . . . adhesion layer, 73 . . . seed layer, 74 . . . second copper layer, 80 . . . insulator, 80 . . . interlayer insulating film, 90 . . . conductor layer, 93 . . . seed layer, 94 . . . copper layer, 100 . . . insulating layer, 110 . . . corrosion prevention film, 141 . . . support body, 142 . . . bonding layer, 143 . . . support body, 144 . . . bonding layer, S1 . . . first surface, S2 . . . second surface

What is claimed is:

1. A wiring substrate comprising:
a glass substrate which has a first surface and a second surface, the second surface serving as a back surface of the first surface, and the second surface provided with one or more through holes each extending from the first surface to the second surface;
a conductor layer provided on a side wall of each of the one or more through holes and the second surface; and
an insulator provided on an inside of each of the one or more through holes, wherein
a surface roughness of the conductor layer provided on the side wall of each of the one or more through holes is larger than a surface roughness of the conductor layer provided on the second surface.

2. The wiring substrate according to claim 1, wherein an arithmetic surface roughness Ra of the conductor layer provided on the side wall of each of the one or more through holes is between 150 nm and 1000 nm.

3. The wiring substrate according to claim 2, wherein the arithmetic surface roughness Ra of the conductor layer provided on the second surface is 100 nm or less.

4. The wiring substrate according to claim 1, further comprising a corrosion prevention film having a discontinuous portion and provided between the conductor layer and the insulator, the conductor layer being provided on the side wall of each of the one or more through holes.

5. The wiring substrate according to claim 1, wherein the surface roughness of the conductor layer provided on the side wall of each of the one or more through holes increases in a direction from a side close to the second surface to a side close to the first surface.

6. The wiring substrate according to claim 4, wherein the surface roughness of the conductor layer provided on the side wall of each of the one or more through holes increases in a direction from a side close to the first surface to a side close to the second surface.

7. A manufacturing method of a wiring substrate, the method comprising:
forming a first conductor layer on a first surface of a glass substrate having the first surface and a second surface, the second surface serving as a back surface of the first surface;
forming one or more modified portions on the glass substrate by irradiating the glass substrate with a laser light;
forming one or more through holes at positions of the one or more modified portions, respectively, by etching the second surface of the glass substrate on which the first conductor layer is formed; and
forming a second conductor layer on the second surface of the glass substrate and the inner wall of each of the one or more through holes, wherein
a surface roughness of the second conductor layer provided on the inner wall of each of the one or more through holes is larger than a surface roughness of the second conductor layer provided on the second surface.

8. The manufacturing method of the wiring substrate according to claim 7, wherein forming the second conductor layer includes:
providing a seed layer on the second surface of the glass substrate and the inner wall of each of the one or more through holes;
forming the second conductor layer on the seed layer by electrolytic copper plating; and
removing an unnecessary portion from the seed layer by etching, wherein
the one or more through holes is smaller in liquid flow amount in the electrolytic copper plating than the second surface.

9. The manufacturing method of the wiring substrate according to claim 7, wherein forming the second conductor layer includes:
providing a seed layer on the second surface of the glass substrate and the inner wall of each of the one or more through holes;
forming the second conductor layer on the seed layer by electrolytic copper plating;
forming a corrosion prevention film having a discontinuous portion on a part of the second conductor layer, the part being provided on the inner wall of each of the one or more through holes; and
etching the second conductor layer such that a part on which the corrosion prevention film is not formed is smaller in film thickness than the part on which the corrosion prevention film is formed.

10. The manufacturing method of the wiring substrate according to claim 9, wherein forming the corrosion prevention film having the discontinuous portion includes:
providing, on the second surface of the glass substrate, a mask having an opening at each of positions of the one or more through holes;
providing, on the inner wall of each of the one or more through holes, the corrosion prevention film having the discontinuous portion; and
removing the mask.

11. The manufacturing method of the wiring substrate according to claim 9, wherein forming the corrosion prevention film having the discontinuous portion includes:
providing, on the second surface of the glass substrate and the inner wall of each of the one or more through holes, a corrosion prevention film which is a continuous film; and
removing the corrosion prevention film from the second surface of the glass substrate by dry etching and also forming the corrosion prevention film having the discontinuous portion on the inner wall of each of the one or more through holes.
